(19) United States
(12) Patent Application Publication
(10) Pub. No.: US 2010/0247764 A1
(43) Pub. Date: Sep. 30, 2010

(54) Method For Surface Treatment of Ti-Al Alloy and Ti-Al Alloy Obtained by The Method

(76) Inventors: Takanori Watanabe, Hyogo (JP); Hideaki Iwamura, Hyogo (JP); Koji Nishikawa, Hyogo (JP)

Correspondence Address: WOOD, PHILLIPS, KATZ, CLARK & MORTIMER, 500 W. MADISON STREET, SUITE 3800, CHICAGO, IL, 60661, US

(21) Appl. No.: 12/679,792

(22) PCT Filed: Oct. 22, 2008
(86) PCT No.: PCT/JP2008/069585

§ 371 Date: May 24, 2010

(30) Foreign Application Priority Data
Oct. 24, 2007 (JP) 2007-275925

(51) Int. Cl. C23C 16/00

(52) U.S. Cl. 427/248.1

(57) ABSTRACT

There is provided a surface treatment method for improving high temperature resistance oxidizability of a Ti—Al alloy in a manner suitable for mass production and the Ti—Al alloy. A Ti—Al alloy base material containing 15 at % or more to 55 at % or less of Al is heated and held in a gas atmosphere containing a fluorine source gas to form a fluorine inspissation layer with a thickness of 0.1 μm or more to 10 μm or less on the surface of the Ti—Al alloy base material, and a maximum concentration of F in the fluorine inspissation layer is made to be 2 at % or more to 35 at % or less. Thereby, when exposed to a high temperature oxidizing atmosphere, the surface of the Ti—Al alloy base is coated with an Al₂O₃ coating film having extremely low oxygen permeability. The alloy hence has excellent insusceptibility to high temperature oxidation. Thus, the poor insusceptibility to high temperature oxidation, which is a most serious disadvantage of the Ti—Al alloy which is lightweight and has high temperature strength, can be improved in a manner suitable for mass production. Therefore, the alloy can be used suitably for a supercharger turbine wheel, an engine valve, turbine blades for a gas turbine or the like, for example.

### TECHNICAL FIELD

The present invention relates to a surface treatment method to improve high temperature resistance oxidizability by forming a fluorine inspissation layer on a surface of Ti—Al alloy, and a Ti—Al alloy obtained by the method.

### RELATED ART

A Ti—Al alloy has a characteristic so the strength of a Ti—Al intermetallic compound is not reduced but increased until the temperature thereof reaches to around 800° C.; thus, the Ti—Al alloy is used as a high temperature material. Moreover, the Ti—Al alloy has a characteristic of which a specific gravity is lighter than Ti, and approximately half in comparison with a Ni group superalloy such as Inconel 713C, generally employed as refractory metal, which is extremely lightweight. Therefore, the Ti—Al alloy is applied to a turbine wheel for superchargers, engine valves of an automobile or the like to improve fuel consumption, response and performance of an engine for speeding up, for example. Moreover, by applying to a turbine blade of a gas-turbine or the like, a centrifugal force generated by rotation and a creep phenomenon can be reduced. Thus, the Ti—Al alloy is expected as a next-generation high temperature material having various possibilities.

The Ti—Al alloy is superior in oxidation resistance in comparison with a normal Ti alloy under a temperature of 800° C. or less; however, there is a problem where oxidation resistance is suddenly deteriorated if the temperature excesses 800° C. As such, in a temperature range over 800° C., the Ti—Al alloy is remarkably inferior in high temperature resistance oxidizability in comparison with the above-mentioned Ni group superalloy; thus not common as a high temperature material in practical use. Therefore, in order to make the Ti—Al alloy common, it is essential to improve oxidation resistance in a high temperature, and in order to realize the same, a method to add a third element and a method by various surface treatments or the like have been considered and disclosed.

### Patent Document 1: JP 2569712(B)

### Patent Document 2: JP H06-033172(A)

### Patent Document 3: JP H05-078817(A)

### Patent Document 4: JP H05-287421(A)

### Patent Document 5: JP 2002-332569(A)

### Patent Document 6: JP H09-170063(A)

### Patent Document 7: JP 3358796(B)

### Patent Document 8: JP H06-322509(A)

### Patent Document 9: JP H06-322511(A)

In Patent Document 1, 5% to 20% of Cr is added to the Ti—Al alloy as the third element to improve high temperature resistance oxidizability. However, as an effect, although weight reduction by oxidation is reduced in comparison with a conventional alloy and weight is not increased, it shows an oxide film having detachability is formed; thus, it is impossible to regard for a stable oxide film inhibiting progression of oxidation to be formed, and there is a problem where oxidation resistance is not necessarily sufficient for practical use.

In addition, in Patent Document 2, oxidation resistance is improved by the method to add 0.004 at % to 1.0 at % of at least one of the halogens among F, Cl, Br and I into the Ti—Al alloy; however, when the halogens of which are over 1.0 at % is added, ductility is decreased, and it is impossible to add a large quantity of halogens so as to exert a sufficient effect.

In the same manner, it has been reported where oxidation resistance is improved by the method to add Mo, Nb, Si, Ta, W or the like as the third element; however, it is necessary to add a large amount of these elements to improve oxidation resistance to the level equal to the Ni group superalloy. Thus, the drop of room temperature ductility of Ti—Al alloy becomes remarkable when adding a large amount of the third element; therefore, it is not an effective method in consideration of utility. Thus, it is required to improve the Ti—Al alloy by a surface treatment method or by both additions of the third elements and a surface treatment, not by alloying the third element or the like on the base material itself.

### SUMMARY OF THE INVENTION

### Problem to be Solved by the Invention

As an improvement method by a surface treatment, Patent Documents 3, 4 and 5 disclose a method to improve high temperature resistance oxidizability by forming a reforming layer in which other elements are entered in the surface part of the Ti—Al alloy.

Patent Document 3 employs a method to attach Mo, W on a surface of the Ti—Al alloy by using an ion sputtering method, ion plating method, a powder packing method, and then thermally diffuse Mo, W in a base material by heating it to 1450° C. or less. However, in the method, it is not simple to form a uniform concentration layer which appears to oxidation resistance and a uniform and sequential Al₂O₃ film which suppresses the development of oxidation; furthermore, the method is problematic with respect to productivity.

Patent Document 4 discloses a method to improve oxidation resistance by ion implantation of P, As, Sb, Se, and Te in the surface. Patent Document 5 discloses a method to implant a fluorine ion in the surface by using a plasma base ion implantation also applicable to a product with a complicated shape. However, such processing requires to be carried out in a high vacuum atmosphere by using an expensive ion implantation equipment; thus, even if it is effective to improve oxidation resistance, it is not a practical method on phases of cost and mass production.

Patent Document 6 is directed to improve oxidation resistance by a method to heat the Ti—Al alloy in a state in which a halogen and/or a compound containing a halogen exist on the surface. In order to realize the method, Embodiment 1 of the Patent Document 6 discloses a method for removing an adhesion product of the surface until metallic luster appears after sealing and heating together with a sodium chloride powder at 790° C. for 150 hours, and Embodiment 3 discloses a method to carry out ion implantation. However, these methods are not practical for mass production, either.

Patent Document 7 discloses a method for improving oxidation resistance by applying mechanical energy to a surface part of the Ti—Al alloy in the state of which a material containing an oxide with a smaller absolute value of standard free energy in comparison with Al₂O₃, and forming a metal alloy layer superior in oxidation resistance on the surface of the base material. The method using shot peening is shown as an effective method as a giving method of mechanical energy. However, although the method using shot peening is a method applicable to parts with some complicated configurations, it is not always easy to form a uniform and sufficient reforming layer on the entire surface of the processing product; thus, sufficient productivity cannot be secured.

On the other hand, Patent Document 8 discloses a method to form a minute Al₂O₃ film by heating for 0.2 hours or more to 700° C. to 1125° C. after attaching or applying a compound containing at least one of the halogens of F, Cl, Br, and I in the form of a solid or a liquid on the surface. Patent Document 9 discloses a method to form a minute Al₂O₃ film by heating mixed gasses containing 0.1 vol % or more of oxygen containing at least one of the halogens of F, Cl, Br, and I.

In Patent Document 8, it is necessary to attach and apply a halide in the form of a solid or liquid on the surface; however, there is a problem where it is extremely hard to uniformly melt and attach the halide in the form of a solid or liquid on the surface of the processing product at the time of heating. Moreover, since all of the halide melted and applied is not necessary reacted uniformly with the surface of the workpiece, so it is hard to form a uniform reaction layer; thus, the method is not suitable for mass production.

Regarding Patent Document 9, it is considered as superior in throwing power and control of the concentration or the like of the surface treatment layer by using a gaseous halogen. However, when a mixing atmosphere containing halogen and oxygen has high causticity, and if processing is carried out by heating to a high temperature of 700° C. to 1125° C., at least for a reactor wall material on which such processing is applied, requires high temperature corrosion resistance. Thereby, as a result, the invention of Patent Document 9 has a problem where the processing unit becomes expensive and a reactor wall material should be replaced often; thus, not suitable for mass production. Moreover, oxidation with high temperatures of 700° C. or more to form an Al₂O₃ film is carried out at the same time; therefore, when assuming a case to incorporate as parts, there is high possibility to cause a problem regarding dimensional accuracy. Even if a post-processing is carried out on a portion requiring dimensional accuracy, it is hard to process the surface of product having a hard oxide film with high precision. Moreover, necessity of welding with the other parts is assumed for practical use; however, it is substantially impossible.

As described above, in order to improve high temperature resistance oxidizability of the Ti—Al alloy, it is considered for the most effective method to coat particularly the surface of the Ti—Al alloy base material with a uniform Al₂O₃ film having a low permeability of oxygen in a resulting oxidation layer formed in a high temperature oxidation atmosphere; however, although many study results and patent documents are disclosed about the method, effective improved means superior in productivity and mass productivity has not yet been particularly reported.

In other words, the present invention provides a surface treatment method of the Ti—Al alloy with a relatively low temperature suitable for mass production, and a Ti—Al alloy that allows to form thereon a uniform Al₂O₃ film superior in oxidation resistance when exposed to a high temperature oxidation atmosphere by forming a reforming layer on the surface of the Ti—Al alloy.

### Means for Solving the Problem

In other words, a surface treatment method of the Ti—Al alloy of the present invention is directed to form a fluorine inspissation layer having a thickness of 0.1 μm or more to 10 μm or less on a surface of the Ti—Al alloy base material containing 15 at % or more to 55 at % or less of Al by heating and holding the Ti—Al alloy base material in an atmosphere containing fluorine source gas at 100° C. to 500° C.

In addition, in the Ti—Al alloy of the present invention, the Ti—Al alloy base material containing 15 at % or more to 55 at % or less of Al has a fluorine inspissation layer having a thickness of 0.1 μm or more to 10 μm or less on a surface part of the Ti—Al alloy base material, and a maximum concentration of F in the fluorine inspissation layer is 2 at % or more to 35 at % or less.

### EFFECT OF THE INVENTION

In the surface treatment method of the Ti—Al alloy according to the present invention, the Ti—Al alloy base material containing 15 at % or more to 55 at % or less of Al is heated and held in an atmosphere containing fluorine source gas at 100° C. to 500° C. to form a fluorine inspissation layer having a thickness of 0.1 μm or more to 10 μm or less on the surface of the Ti—Al alloy base material. By using gas as the fluorine source, it is possible to simply form a uniform fluorine inspissation layer on the surface of a workpiece regardless of its shape, and extremely suitable for mass production. Moreover, according to the formation of the fluorine inspissation layer on the surface of the Ti—Al alloy base material, when exposed to a high temperature oxidation atmosphere, an oxidation layer coated with a uniform and sequential Al₂O₃ film which is superior in oxidation resistance on the surface of the Ti—Al alloy base material is formed, and the Al₂O₃ film prevents oxygen from entering in the Ti—Al alloy base material to suppress progression of oxidation; thereby, high temperature resistance oxidizability of the Ti—Al alloy can be significantly improved. According to such processing by heating in the gas atmosphere in a comparatively low temperature range suitable for mass production, high temperature resistance oxidizability of the Ti—Al alloy base material can be significantly improved.

In the surface treatment method of the Ti—Al alloy of the present invention, in a case where the maximum concentration of F in the fluorine inspissation layer after the heating and holding is made at 2 at % or more to 35 at % or less, when exposed to a high temperature oxidation atmosphere, the surface of the Ti—Al alloy base material is coated with a uniform and sequential Al₂O₃ film; thereby, high temperature resistance oxidizability can be significantly improved.

In the surface treatment method of the Ti—Al alloy of the present invention, in a case where aluminum fluoride such as AlF₃ is not substantially contained in the fluorine inspissation layer after the heating and holding, when exposed to a high temperature oxidation atmosphere, the surface of the Ti—Al alloy base material is coated with a uniform and sequential Al₂O₃ film; thereby, high temperature resistance oxidizability can be significantly improved.

In addition, in the Ti—Al alloy of the present invention, since the Ti—Al alloy base material containing 15 at % or more to 55 at % or less of Al has a fluorine inspissation layer having thickness of 0.1 μm or more to 10 μm or less on the surface part of the Ti—Al alloy, and the maximum concentration of F in the fluorine inspissation layer is 2 at % or more to 35 at % or less, when exposed to a high temperature oxidation atmosphere, an oxidation layer coated with a uniform and sequential Al₂O₃ film is formed on the surface, and the Al₂O₃ film prevents oxygen from entering in the Ti—Al alloy base material to suppress the progression of oxidation; thereby, the Ti—Al alloy is superior in high temperature resistance oxidizability.

In the surface treatment method of the Ti—Al alloy according to the present invention, in a case where aluminum fluoride such as AlF₃ is not substantially contained in the fluorine inspissation layer, when exposed to a high temperature oxidation atmosphere, the surface of the Ti—Al alloy base material is coated with a uniform and sequential Al₂O₃ film; thereby, high temperature resistance oxidizability can be significantly improved.

### BRIEF DESCRIPTION OF DRAWINGS

FIG. 1 shows a result of surface X-ray diffraction of a Ti—Al alloy of Example F on which fluorine inspissation processing is applied, and a result of surface X-ray diffraction of a Ti—Al alloy of Comparative Example C.

### BEST MODE FOR CARRYING OUT THE INVENTION

The best mode for carrying out the invention will be explained below.

In a method for surface treatment of a Ti—Al alloy according to the present invention, a workpiece having the Ti—Al alloy as a base material is heated and held to 100° C. to 500° C. in a gas atmosphere containing a fluorine source gas, and a fluorine inspissation layer is formed on the surface of the workpiece.

As the fluorine source gas used for the above described fluorine inspissation processing, fluorine system gas (fluoro-compound gas or gas containing fluorine gas) which is a halogen system substance is used. For such a fluorine system gas, a fluorine compound, e.g., a gas containing NF₃, BF₃, CF₄, SF₆ or the like as a main component and a gas containing F₂ as a main component are used. Usually, the main component gas is diluted with dilution gas such as nitrogen gas, and used as the fluorine system gas. Among the main component gas used for such fluorine system gas, NF₃ is most excellent in terms of reactivity and handling and is practical.

The workpiece having the Ti—Al alloy as a base material which is processed with fluorine system gas is held in a nitrogen gas atmosphere containing for example, NF₃ at a temperature range of 100° C. to 500° C., more preferably 200° C. to 400° C. for 1 to 600 minutes, more preferably 5 to 120 minutes, and NF₃ is decomposed to generate active F; thus, a uniform fluorine inspissation layer having a thickness of 0.1 μm or more to 10 μm or less is formed on the surface of the workpiece. Note that, regarding the processing temperature and the processing time, a suitable condition can be set so that the objective fluorine inspissation layer is reliably formed depending on the material or the surface condition of the workpiece having the Ti—Al alloy as a base material which is a processing product. In the conditions regarding a concentration of the fluorine compound or fluorine in the fluorine system gas atmosphere, though depending on the kinds of gases employed thereto is usually 0.1 vol % to 10 vol % preferably.

A composition of the Ti—Al alloy base material in the present invention contains 15 at % or more to 55 at % or less of Al. The content of Al within the above mentioned concentration range allows obtaining the Ti—Al alloy not only having a superior high temperature strength but having a room temperature ductility. In a case where the content of Al is less than 15 at %, in an aspect of strength, a mixed structure of a-Ti alloy and a Ti₃Al phase is produced, then a high temperature strength is decreased. In addition, in an aspect of high temperature resistance oxidizability, there is a high possibility where Al sufficient for a uniform and successive Al₂O₃ film to coat the surface of the Ti—Al alloy base material cannot be supplied from the base material. In addition, if the content of Al exceeds 55 at %, the mixed layer comprising a TiAl phase, a TiAl₂ phase and a TiAl₃ phase is obtained, and a drastic embrittlement of the base material is caused; thus, a problem as to strength is generated.

Moreover, in order to improve poor room temperature ductility which is another defect of the Ti—Al alloy, usually at least one kind of element such as Cr, Mn, V, and B is included by 10 at % or less and usually it is known for where high temperature resistance oxidizability is remarkably decreased by adding such elements. However, according to the method of the present invention, in a case where the Al concentration of the Ti—Al alloy is 15 at % or more, an improvement effect of the high temperature resistance oxidizability can be fully expected; thus, the Ti—Al alloy in which 15 at % or more to 55 at % or less of the above described elements are added is included as an applicable range of the present invention.

Furthermore, a surface treatment of the Ti—Al alloy of the present invention is applicable to a processing product regardless of its producing method such as casting, forging, cutting, rolling or the like.

In the present invention, it is not exactly known why high temperature resistance oxidizability of the Ti—Al alloy is drastically improved by forming the fluorine inspissation layer on the surface of the Ti—Al alloy; however, the following mechanism may be inferred. In other words, a reason why usual Ti—Al alloy without special treatment has poor high temperature resistance oxidizability is as a form of an oxidation layer formed in high temperature oxidation, an oxidation layer with a multilayer structure in which an oxidation layer rich in TiO₂ and an oxidation layer rich in Al₂O₃ are alternately formed is formed, and TiO₂ of high permeability of oxygen is mixed in the oxidation layer rich in Al₂O₃; thus, the oxidation layer rich in Al₂O₃ is not functioned as a protective oxide film; therefore regardless of high content of Al and poor in the high temperature resistance oxidizability. On the other hand, in a case where the fluorine inspissation layer according to the present invention is formed on the surface of the Ti—Al alloy beforehand, it is considered a mixed oxidation layer of Ti and Al is formed on the uppermost surface as a form of an oxidation layer formed by high temperature oxidation; however, namely the surface of the Ti—Al alloy base material is coated with a minute and uniform Al₂O₃ film of numbers of μm between the mixed oxidation and the base material, and permeability of the oxygen of the Al₂O₃ films is extremely low; therefore, the entrance of oxygen in the Ti—Al alloy base material is suppressed; thus, progression of oxidation of the base material is suppressed.

Moreover, in a case where the Ti—Al alloy of the present invention is exposed to a high temperature oxidation atmosphere, a reason of which such an oxidation layer structure having a protective film is produced is considered that the entering fluorine has a strong affinity with Al rather than Ti; thus, in an initial stage of oxidation, Ti having comparatively low affinity with the entering fluorine preferentially generates an oxidation reaction, thereby concentration of Al is generated on a side of the base material, then oxidation is progressed, and a part of which Al is concentrated is oxidized, thereby uniform and sequentially Al₂O₃ film having extremely high Al concentration is formed.

Thickness of the fluorine inspissation layer formed on the surface of the Ti—Al alloy according to the present invention is 0.1 μm or more to 10 μm or less. If the thickness of the fluorine inspissation layer is less than 0.1 μm, an effect of the fluorine entered as mentioned above to attract Al in the alloy becomes insufficient; thus, there is a possibility where the thickness of the obtained Al₂O₃ becomes insufficient or uneven. On the other hand, if the thickness of the fluorine inspissation layer excesses 10 μm, a thick region with a decreased Al concentration is formed at the base material side of the fluorine inspissation layer having a strong affinity with Al; thereby, high temperature resistance oxidizability of the region is considerably decreased, thus occasionally, there is a possibility where high temperature resistance oxidizability is decreased equal to or more than that of the unprocessed material. More preferably, the thickness of the fluorine inspissation layer is about 5 μm or less.

Moreover, in the present invention, the maximum concentration of F in the fluorine inspissation layer formed on the surface of the Ti—Al alloy is 2 at % or more to 35 at %. If the maximum concentration of F in the fluorine inspissation layer is less than 2 at %, a quantity of fluorine which is entered is too little; thus, an effect to attract Al in the Ti—Al alloy becomes insufficient, and there is a possibility where the thickness of the resulting Al₂O₃ film is insufficient or uneven. On the other hand, when the maximum concentration of F exceeds 35 at %, even if the fluorine inspissation layer is a thin layer of 10 μm or less, the region where the Al concentration is significantly decreased is formed on the base material side of the fluorine inspissation layer, and high temperature resistance oxidizability of the region is significantly decreased; furthermore, fluoride such as AlF₃ is formed and formation of a uniform Al₂O₃ film is obstructed, thereby oxidation resistance is deteriorated; thus, there is a possibility where high temperature resistance oxidizability is deteriorated equal to or more than an unprocessed material by a case.

Thus, in the present invention, a surface treatment suitable for mass production processing such as fluorination processing to the Ti—Al alloy is carried out, and an appropriate fluorine inspissation layer is formed on the surface; thereby, improvement of the high temperature resistance oxidizability which is the biggest problem when the Ti—Al alloy is employed as a high temperature material is made possible.

Next, examples of the present invention will be described below.

### EXAMPLE 1

99.8% purity of sponge titanium and 99.99% purity of aluminum are weighed so as to obtain target compositions and an ingot (Ti-48 at % Al) was prepared by using a melting furnace, and after once carrying out evacuation to 10⁻⁴ Torr or more, melted and solidified under an Ar gas atmosphere. A plate-like test piece of 30 mm*10 mm*3 mm is cut from the ingot, and after grinding the surface of the test piece with a SiC paper of No. 1000, the test piece is subjected to ultrasonic cleaning in acetone, thereby the test piece is obtained.

As the test pieces for Examples A-E, a fluorine inspissation is carried out by a method to hold the test pieces at 200° C. to 400° C. for 5 to 120 minutes in a fluorine source gas atmosphere containing NF₃ gas of 2 vol % and comprising the rest N₂ gas and impurity gas; thereby, the test pieces were prepared. A thickness and a maximum F concentration of the fluorine inspissation layer were measured by using ESCA (an X-ray photoelectron analyzer) and EPMA (an electron beam micro analyzer).

In order to investigate high temperature resistance oxidizability of each test piece subjected to the above-described fluorine inspissation processing, an oxidation test is carried out by heating 1000° C.*100 hr in an ambient atmosphere by using a resistance heating electric furnace. The test piece is subjected to the test in a condition where the test piece is put in an Al₂O₃ crucible so the weight increase measurement is carried out together with an exfoliating oxide film. In addition, a test piece of Comparative Example A without fluorine inspissation processing, and a test piece of Comparative Example B held in a fluorine source gas atmosphere containing 2 vol % of NF₃ gas and comprising the rest N₂ gas and impurity gas at 600° C. for 10 minutes are subjected to similar oxidation tests. The results of compiling the tests are shown in the following Table 1.

TABLE 1

| | Condition | Thickness of | Maximum | |
|---|---|---|---|---|
| | of Fluorine | Fluorine | F Concen- | Oxidation |
| | Inspissation | Inspissation | tration | Increase |
| | Processing | Processing (μm) | (at %) | (g/m²) |
| Comparative | — | 0 | 0 | 336.7 |
| Example A | | | | |
| Example A | 200° C. * 30 min | 0.1 | 2.0 | 3.5 |
| Example B | 300° C. * 5 min | 0.3 | 4.2 | 6.8 |
| Example C | 300° C. * 30 min | 1 | 8.6 | 7.9 |
| Example D | 300° C. * 120 min | 3 | 18 | 5.4 |
| Example E | 400° C. * 30 min | 10 | 33 | 31.2 |
| Comparative | 600° C. * 10 min | 17 | 52 | 127.1 |
| Example B | | | | |

As indicated in the results of Table 1, in Example 1, the oxidation increase rate was one-tenth or less in comparison with Comparative Example A of which no fluorine inspissation processing was carried out; thus, it was found oxidation resistance was remarkably improved. In addition, in a case where the fluorine inspissation layer is thick as indicated in Comparative Example B, increase in quantity by the oxidation test grows; thus, it was found there is an appropriate thickness for the fluorine inspissation processing layer.

Moreover, according to the results of Example 1, it was found the appropriate thickness of the fluorine inspissation layer of the present invention is 0.1 μm or more to 10 μm or less, and more preferably, 0.1 μm or more to 5 μm or less. In addition, as a result of analyzing a cross section after the oxidation test by EPMA and the like, it was found that uniform and successive oxidation layers of Al with high concentration were formed on the surface of the base material.

### EXAMPLE 2

In order to examine an influence of the maximum F concentration in the fluorine inspissation layer, a test piece similar to Example 1 was prepared, and a process to change the maximum F concentration of the fluorine inspissation layer without changing the thickness thereof is carried out by changing the concentration of the fluorine source gas in the atmosphere. The test piece of Example F is held in a fluorine source gas atmosphere containing 3 vol % of NF₃ gas and comprising the rest N₂ gas and impurity gas; moreover, the test piece of Comparative Example C is held in a fluorine source gas atmosphere containing 30 vol % of NF₃ gas and comprising the rest N2 gas and impurity gas at 350° C. for 60 minutes. Afterwards, an oxidation test of 1000° C.*100 hr (in atmospheric air) similar to Example 1 was carried out. Results of the test are shown in Table 2.

TABLE 2

| | | Thickness of | Maximum | |
|---|---|---|---|---|
| | NF₃ | Fluorine | F Concen- | Oxidation |
| | Concentration | Inspissation | tration | Increase |
| | (vol %) | Processing (μm) | (at %) | (g/m²) |
| Example F | 3 | 7 | 23 | 10.2 |
| Comparative | 30 | 7 | 41 | 57.1 |
| Example C | | | | |

As shown in the results of Table 2, it is found even in a case where the thickness of the fluorine inspissation layer is not so thick when the F concentration in the fluorine inspissation layer is too high, increased quantity of the oxidation increases after the oxidation test.

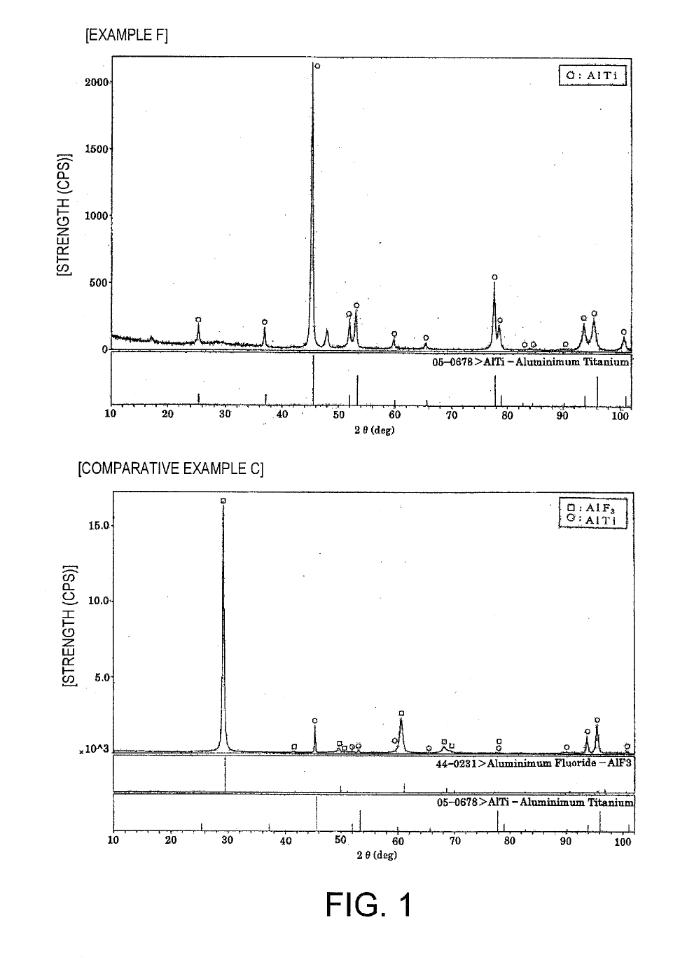

The result of identification of the surface product with respect to the test piece after carrying out the fluorine inspissation processing of Example F and the test piece after carrying out the fluorine inspissation processing of the Comparative Example C by using an X-ray diffractometer is shown in FIG. 1.

As a result of FIG. 1, on the test piece under a fluorine inspissation processing condition of Comparative Example C, a peak of the AlF₃ which is fluoride of Al was clearly observed; on the other hand, on the test piece under a fluorine inspissation processing condition of Example F, a peak of fluoride was not found and only a peak of TiAl which is a major component of a base was observed. This result indicates that when a concentration of F entered by the fluorine inspissation processing was not too high, formation of a fluoride such as AlF₃, which was considered to inhibit the formation of uniform Al₂O₃ film if exposed to oxidative atmosphere, was suppressed, and the results of Table 2 also shows the concentration of F which is entered is also one of the important factors for oxidation resistance of the Ti—Al alloy.

Thus, according to the results of Tables 1 and 2, an appropriate range of the maximum F concentration in the fluorine inspissation layer of the Ti—Al alloy of the present invention is 2 at % or more to 35 at % or less, and more preferably, 2 at % or more to 25 at % or less.

### EXAMPLE 3

In order to examine an influence of the Al content in the Ti—Al alloy, a plate-like test piece of 30 mm*10 mm*3 mm is cut from an ingot prepared by weighing, melting, and solidifying an ingredient so as to obtain the target composition of which Al contents thereof are 15 at %, 30 at %, 45 at %, and 55 at %, in a similar manner to Example 1, then a surface of the ingot is ground then subjected to ultrasonic cleaning in acetone to prepare the test piece.

After the test pieces having different compositions were subjected to fluorine inspissation processing by holding the test pieces in fluorine source gas atmospheres containing 2 vol % of NF₃ gas and comprising the rest N2 gas and impurity gas for 300° C.*120 minutes, then an oxidation test of 1000° C.*100 hr was carried out in atmospheric air; thus, the results of the test are shown in the following Table 3. In addition, a thickness of the fluorine inspissation layer of the test piece subjected to the fluorine inspissation processing was 3 μm±1 μm, and a maximum F concentration in the fluorine inspissation layer was within a range from 18 at %±5 at %. As Comparative Examples D to G, the Ti—Al alloy containing 15 at %, 30 at %, 45 at %, and 55 at % of Al without carrying out the fluorine inspissation process was subjected to an oxidation test.

TABLE 3

| | | Condition | |
|---|---|---|---|
| | | of Fluorine | Oxidation |
| | Alloy | Inspissation | Increase |
| | Composition | Processing | (g/m²) |
| Example G | Ti—15Al | 300° C. * 120 min | 89.7 |
| Example H | Ti—30Al | 300° C. * 120 min | 37.8 |
| Example I | Ti—45Al | 300° C. * 120 min | 6.9 |
| Example J | Ti—55Al | 300° C. * 120 min | 4.2 |
| Comparative | Ti—15Al | None | 1126.4 |
| Example D | | | |
| Comparative | Ti—30Al | None | 592.6 |
| Example E | | | |
| Comparative | Ti—45Al | None | 353.2 |
| Example F | | | |
| Comparative | Ti—55Al | None | 297.8 |
| Example G | | | |

As shown in the results of Table 3, according to the effect of the fluorine inspissation process, in comparison with a case where no fluorine inspissation processing is applied, oxidation is respectively increased by one-tenth or less; thus, improvement of oxidation resistance was found. Therefore, it was found a content of Al in the Ti—Al alloy of the present invention is effective within a range of 15 at % or more to 55 at % or less. However, as the content of Al in the Ti—Al alloy is decreased, an absolute value of the oxidation increase is considerably increased; thus, more preferably, the content of Al is 45 at % or more to 55 at % or less.

### EXAMPLE 4

In order to confirm an effect of the third element added for improvement of room temperature ductility of the Ti—Al alloy, a result confirming oxidation resistance in a case where Cr, Mn, and V were added in a similar manner to Example 3 is shown in the following Table 4. Fluorine inspissation processing of Examples K to M was carried out under a condition to hold in the fluorine source gas atmospheres containing 1 vol % of NF₃ gas and comprising the rest N2 gas and impurity gas for 300° C.*30 minutes. As Comparative Examples H-J, the Ti—Al alloy added Cr, Mn, and V without carrying our fluorine inspissation processing were subjected to an oxidation test.

TABLE 4

| | | Condition | |
|---|---|---|---|
| | | of Fluorine | Oxidation |
| | Alloy | Inspissation | Increase |
| | Composition | Processing | (g/m²) |
| Example K | Ti—48Al—2Cr | 300° C. * 30 min | 7.7 |
| Example L | Ti—48Al—2Mn | 300° C. * 30 min | 8.6 |
| Example M | Ti—48Al—2V | 300° C. * 30 min | 9.1 |
| Comparative | Ti—48Al—2Cr | None | 447.7 |
| Example H | | | |
| Comparative | Ti—48Al—2Mn | None | 465.1 |
| Example I | | | |
| Comparative | Ti—48Al—2V | None | 474.3 |
| Example J | | | |

As shown in the results of Table 4, in comparison with a case where no fluorine inspissation processing was applied, remarkable improvement of oxidation resistance by the effect of the fluorine inspissation processing was found; therefore, including a case where the third element is added in the Ti—Al alloy, the fluorine inspissation processing method of the present invention is remarkably effective to improve high temperature resistance oxidizability of the Ti—Al alloy and the Ti—Al alloy subjected to the fluorine inspissation processing by the method of the present invention has prominent high temperature resistance oxidizability.

### INDUSTRIAL APPLICABILITY

The present invention can be used as a surface treatment method which can improve high temperature resistance oxidizability of a Ti—Al alloy and is extremely suitable for mass production. Moreover, the Ti—Al alloy of the present invention can be suitably used as a member required having light weight and high temperature strength.

1. A method for surface treatment of a Ti—Al alloy comprising heating and holding a Ti—Al alloy base material containing 15 at % or more to 55 at % or less of Al, in an atmosphere containing a fluorine source gas at 100° C. to 500° C. to form a fluorine inspissation layer with a thickness of 0.1 μm or more to 10 μm or less on a surface of the Ti—Al alloy base material.

2. The method for surface treatment of the Ti—Al alloy according to claim 1, wherein a maximum concentration of F in the fluorine inspissation layer after the heating and holding is 2 at % or more to 35 at % or less.

3. The method for surface treatment of the Ti—Al alloy according to claim 1, wherein aluminum fluoride such as AlF3 is not substantially contained in the fluorine inspissation layer after the heating and holding.

4. A Ti—Al alloy comprising a Ti—Al alloy base material containing 15 at % or more to 55 at % or less of Al, wherein the Ti—Al alloy base material has a fluorine inspissation layer having a thickness of 1 μm or more to 10 μm or less on a surface part thereof, and a maximum concentration of F in the fluorine inspissation layer is 2 at % or more to 35 at % or less.

5. The Ti—Al alloy according to claim 4, wherein the fluorine inspissation layer after the heating and holding does not substantially contain an aluminum fluoride such as AlF3.

6. The method for surface treatment of the Ti—Al alloy according to claim 2, wherein aluminum fluoride such as AlF3 is not substantially contained in the fluorine inspissation layer after the heating and holding.
